(19) United States
(12) Patent Application Publication
(10) Pub. No.: US 2026/0196390 A1
(43) Pub. Date: Jul. 9, 2026

(54) METHOD FOR SEMICONDUCTOR BRIDGE CURRENT PROTECTION BASED ON VANADIUM DIOXIDE THICK-FILM THERMISTOR

(71) Applicant: Hangzhou Dianzi University, Hangzhou (CN)

(72) Inventors: Zhe Kong, Hangzhou (CN); Jianjun Luo, Hangzhou (CN); Aqing Chen, Hangzhou (CN); Xing Duan, Hangzhou (CN); Xiangdong Yuan, Hangzhou (CN)

(21) Appl. No.: 19/440,942

(22) Filed: Jan. 6, 2026

(30) Foreign Application Priority Data
Jan. 8, 2025 (CN) 202510025979.6

(51) Int. Cl. H01C 17/08; H10D 1/00; H10D 89/60

(52) U.S. Cl. CPC H01C 17/08; H10D 1/021; H10D 89/911

(57) ABSTRACT

A method for semiconductor bridge current protection based on vanadium dioxide thick-film thermistor is provided, which relates to the field of semiconductor bridge current protection technologies. A copper, nickel, or gold interdigitated electrode is deposited on an aluminum oxide ceramic substrate. A vanadyl acetylacetonate methanol solution is sprayed onto a surface of the heated interdigitated electrode to obtain a vanadium dioxide thermistor device. This device is connected in parallel with a semiconductor bridge to achieve thermistor-based semiconductor bridge current protection. By adjusting a synthesis method and process, vanadium dioxide with a relatively single valence state can be synthesized, thereby achieving one-step synthesis of M-phase vanadium dioxide directly on the interdigitated electrode. This preparation method avoids a cumbersome process of first preparing vanadium dioxide powder and then transferring it onto the surface of the interdigitated electrode, and the vanadium dioxide can also be more stably bonded to the interdigitated electrode surface.

### CROSS-REFERENCE TO RELATED APPLICATION

This application claims priority to Chinese Patent Application No. 202510025979.6, filed on Jan. 8, 2025, which is herein incorporated by reference in its entirety.

### TECHNICAL FIELD

The disclosure relates to the field of semiconductor bridge current protection technologies, and more particularly to a method for semiconductor bridge current protection based on a vanadium dioxide thick-film thermistor.

### BACKGROUND

A semiconductor bridge (SCB) is an important component of an energizing element. In increasingly complex electromagnetic environments, the energizing element and its circuitry can form an equivalent antenna, which captures energy from the electromagnetic field and converts it into heat, thereby affecting the safety of the device. Many pieces of equipment impose a safety current requirement of 1 ampere (A) per 5 minutes (min) on the energizing element, which demands that a temperature of the semiconductor bridge does not rise to an upper limit specified for the device within 5 min when a 1 A current is applied. To provide effective electromagnetic protection for the semiconductor bridge, a negative temperature coefficient (NTC) thermistor is currently commonly selected to form a parallel circuit with the semiconductor bridge. As current continues to be applied, the temperature of the semiconductor bridge rises, while a resistance of the NTC thermistor gradually decreases, and the current flowing through the semiconductor bridge reduces, thereby achieving a goal of lowering its temperature. However, as device size requirements become smaller, a fabrication process for the NTC thermistor is incompatible with that for the energizing element, which prevents integrated production. Vanadium dioxide (VO₂) is a metal-insulator transition (MIT) material, which has a suitable phase transition temperature of 68 Celsius degrees (° C.). An electrical conductivity of VO₂ can undergo a significant and reversible change with temperature variation. Furthermore, a preparation process of VO₂ is compatible with the integrated fabrication process for the semiconductor bridge, making it an ideal thermistor for parallel connection with the semiconductor bridge in the fabrication of the energizing element. However, the preparation of vanadium dioxide can be achieved through methods such as sol-gel, chemical vapor deposition, and hydrothermal synthesis. Depending on the vanadium source and reducing agent used, a valence state of the synthesized product may vary, thereby forming other vanadium oxides or oxide mixtures.

### SUMMARY

Aiming at the above defects of the related art, the disclosure achieves current protection for the semiconductor bridge by preparing an M-phase vanadium dioxide film. This is accomplished by forming a parallel circuit between a vanadium dioxide thermistor device and the semiconductor bridge. The property of M-phase vanadium dioxide being insulating at low temperatures and transitioning to a metallic phase at high temperatures is utilized, the thermistor device provides a shunting effect on the semiconductor bridge at elevated temperatures, thereby minimizing damage to the semiconductor bridge. By adjusting a synthesis method and process, the disclosure enables the production of vanadium dioxide with a predominantly single-valence state, thereby achieving direct one-step synthesis of M-phase vanadium dioxide on an interdigitated electrode. This approach eliminates a cumbersome process of first preparing vanadium dioxide powder and then transferring it onto the electrode surface. Furthermore, it allows the vanadium dioxide to form a robust bonding with the interdigitated electrode surface, resulting in a stable thermistor device.

The disclosure provides a method for semiconductor bridge current protection based on a vanadium dioxide thick-film thermistor, including the following steps:
S1, dissolving vanadyl acetylacetonate in a methanol solution to obtain a vanadyl acetylacetonate methanol solution;
S2, obtaining an interdigitated electrode, and heating the interdigitated electrode to maintain a temperature of the interdigitated electrode at 300° C. to 400° C. to obtain a heated interdigitated electrode;
S3, spraying the vanadyl acetylacetonate methanol solution obtained in step S1 onto a surface of the heated interdigitated electrode obtained in step S2, where during the spraying, the temperature of the interdigitated electrode is maintained at 300° C. to 400° C., and an M-phase vanadium oxide film with a thickness of 2 microns (μm) to 5 μm is deposited on the surface of the heat interdigitated electrode via spraying;
S4, after the spraying is completed, annealing the interdigitated electrode and the M-phase vanadium oxide film, followed by naturally cooling to room temperature to obtain a thermistor device; where the thermistor device comprises the interdigitated electrode and the M-phase vanadium oxide film deposited thereon; and
S5, connecting the thermistor device in parallel with a semiconductor bridge to achieve thermistor-based semiconductor bridge current protection.

In an embodiment, the step S2 specifically includes: placing a substrate coated with the interdigitated electrode on an electric heating plate for heating. A surface temperature of the electric heating plate is controlled at 300° C. to 400° C.

In an embodiment, the substrate is any one of alumina ceramic and a silicon substrate with a surface-grown oxide layer.

In an embodiment, the spraying in step S3 specifically includes: spraying via an atomizing nozzle.

In an embodiment, the spraying via an atomizing nozzle specifically includes: controlling a distance between the atomizing nozzle and an upper surface of the interdigitated electrode to be 5 centimeters (cm) to 20 cm; and controlling a spray flow rate to be 20 milliliters per minute (mL/min) to 50 mL/min, and controlling a spraying time to be 30 min to 40 min.

In an embodiment, the interdigitated electrode is one selected from the group consisting of a copper interdigitated electrode, a nickel interdigitated electrode, and a gold interdigitated electrode.

Compared to the related art, the disclosure has the following effects.

The prepared vanadium dioxide exhibits a dense structure, strong adhesion to the substrate, and is predominantly in the M-phase. Materials prepared in this manner possess good electrical conductivity at high temperatures along with favorable stability.

The one-step synthesis of vanadium dioxide directly on the surface of the interdigitated electrode simplifies the fabrication process for the thermistor device, while also enhancing its stability.

The spray coating process for depositing vanadium dioxide provided by the disclosure offers strong extensibility. For instance, by adding elements such as tungsten or molybdenum during the spraying process, further adjustment of the phase transition temperature can be achieved, thereby expanding the applicable temperature range of the device.

Through the spray coating method, the thickness of the deposited film is adjustable.

### BRIEF DESCRIPTION OF DRAWINGS

In order to provide a clearer explanation of technical solutions in embodiments of the disclosure or related art, drawings required for use in the embodiments or the related art descriptions will be briefly introduced below. Subsequently, some of the embodiments of the disclosure will be described in detail with reference to the drawings by way of example rather than limitation. The same reference numerals in the drawings indicate the same or similar components or parts. Those skilled in the art should understand that these drawings may not necessarily be drawn to scale.

FIG. 1 illustrates a morphology of vanadium dioxide. As can be seen from FIG. 1, a large number of vanadium dioxide particles are deposited both on finger electrodes of an interdigitated electrode and in gaps between the finger electrodes, with good contact between the particles.

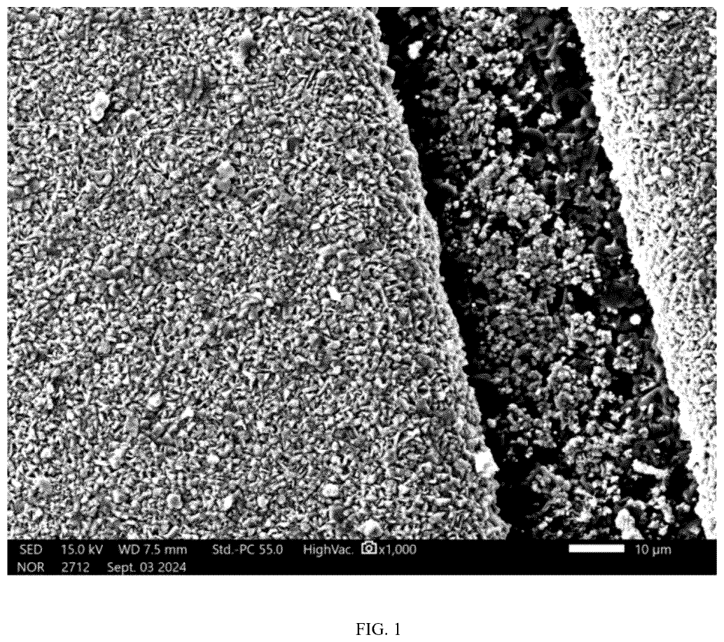

FIG. 2 illustrates a side view of the vanadium dioxide. As can be seen that under these deposition conditions, a film thickness is about 3 μm, the structure is dense, and the contact with the substrate is tight.

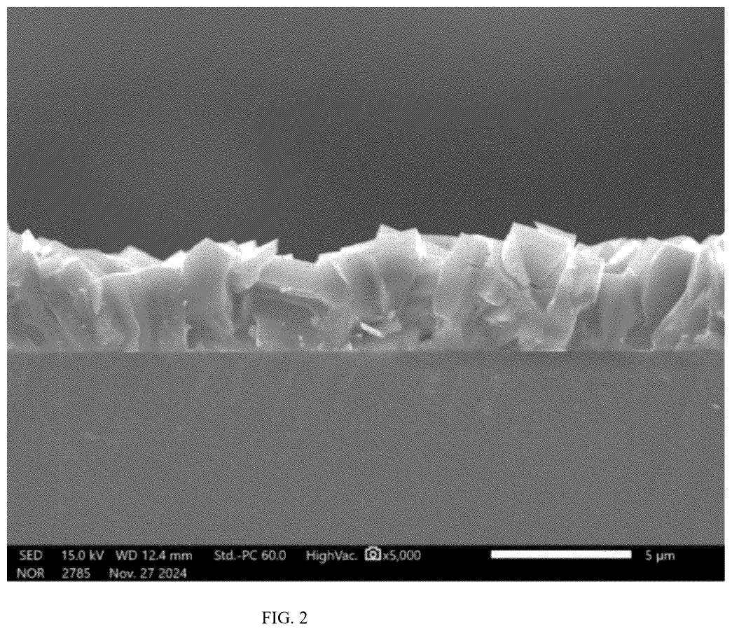

FIG. 3 illustrates an X-Ray diffraction (XRD) pattern of M-phase vanadium dioxide. As can be seen that peaks of the sample are sharp, which indicates good crystallinity. Apart from peaks corresponding to an aluminum oxide (Al₂O₃) substrate, positions of the remaining peaks match those of a standard card for M-phase vanadium dioxide, which indicates that the prepared vanadium dioxide film is in the M-phase.

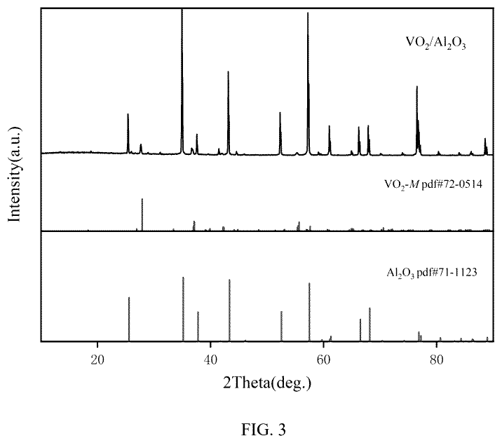

FIG. 4 illustrates a resistance versus temperature curve of a vanadium dioxide thermistor device. At low temperatures, vanadium dioxide is in an insulating state with a resistance of 240 ohms (Ω). After heating, the resistance decreases until the phase transition is complete, at which point vanadium dioxide becomes metallic with a resistance of 5 Ω. When one such device is connected in parallel with an SCB (1 Ω), it can divert ⅙ of the current; when the SCB is connected in parallel with two such thermistor, it can divert 2/7 of the current, which can significantly reduce the heat on the SCB.

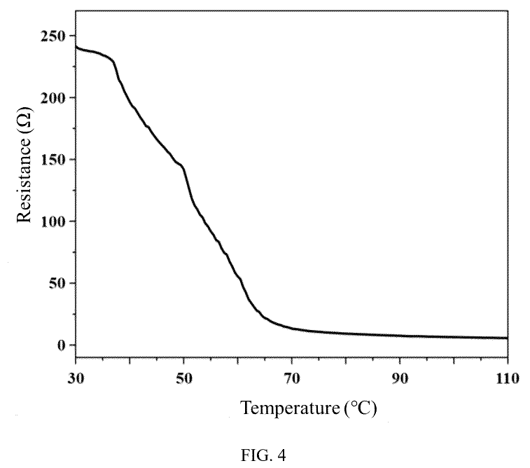

FIG. 5 illustrates a schematic diagram of a relationship between temperature and energization time for a semiconductor bridge at a fixed current before being connected in parallel with the vanadium dioxide thermistor. Curves of different colors represent applied currents of 0.8 A, 1.0 A, and 1.2 A, respectively. As can be seen that at a current of 0.8 A, the temperature on the SCB gradually increases and reaches equilibrium with increasing power on time, stabilizing at 131° C.; at a current of 1.0 A, an equilibrium temperature is 186° C.; at a current of 1.2 A, the SCB circuit breaks due to excessive temperature after 150 seconds(s) of energization, resulting in damage and a sharp drop in temperature.

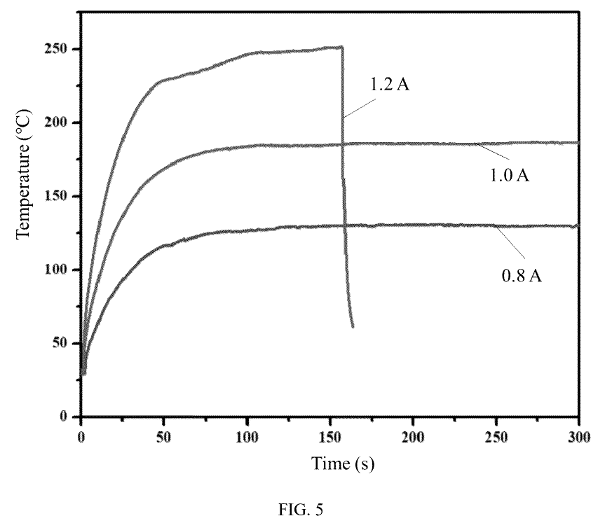

FIG. 6 illustrates a schematic diagram of a relationship between temperature and energization time for the semiconductor bridge at a fixed current after being connected in parallel with the vanadium dioxide thermistor. Curves of different colors represent applied currents of 0.8 A, 1.0 A, and 1.5 A, respectively. As can be seen that within a very short time after the current is applied, the temperature on the SCB rises rapidly. As vanadium dioxide undergoes the phase transition, current is diverted by the vanadium dioxide thermistor, which slows a rate of temperature increase on the SCB, then stabilizes over time. At the current of 0.8 A, the equilibrium temperature is 86° C.; at the current of 1.0 A, the equilibrium temperature is 110° C. ; and at the current of 1.5 A, the equilibrium temperature is 180° C. Comparing the equilibrium temperatures in FIG. 5, it can be observed that the vanadium dioxide thermistor effectively reduces the temperature on the SCB, thereby providing protection and improving a safe current rating of the SCB.

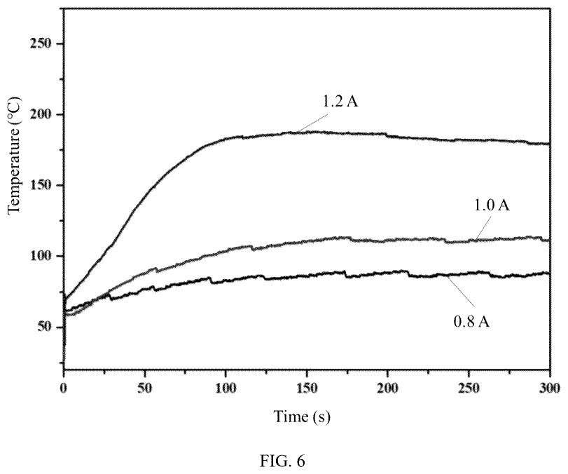

### DETAILED DESCRIPTION OF EMBODIMENTS

In order to make purpose, technical solution and advantages of the disclosure more clear, the disclosure is further described in detail in conjunction with drawings and embodiments. It should be noted that the embodiments described here are merely used to describe the disclosure, is not used to limit the disclosure.

### Embodiment

In step (1), under the room temperature, 2 grams (g) of vanadyl acetylacetonate is dissolved in 50 milliliters (mL) of anhydrous methanol to obtain a vanadyl acetylacetonate methanol solution.

In step (2), a ceramic tile coated with an interdigitated electrode is placed on an electric heating plate with a surface temperature of 400° C. to obtain a heated interdigitated electrode. The interdigitated electrode is fabricated on a 1 cm×1 cm aluminum oxide ceramic substrate. The interdigitated electrode has 15 pairs of interdigitated fingers with a line spacing of 50 μm, a line width of 100 μm, and a finger length of 7.7 millimeters (mm).

In step (3), the vanadyl acetylacetonate methanol solution obtained in step (1) is sprayed onto a surface of the heated interdigitated electrode via an atomizing nozzle, and a distance between the atomizing nozzle and the surface of the electric heating plate is 5 cm.

In step (4), a spray flow rate is controlled at 50 mL/min, a spraying time is controlled at 40 min, and a vanadium dioxide film is prepared with a thickness of 3 μm. The prepared film is thicker than the film prepared by a physical vapor deposition (PVD) method, the process is simpler and the preparation cost is lower.

In step (5), the prepared film (i.e., the vanadium dioxide film) is annealed at 400° C. and argon (Ar₂) atmosphere for 3 hours (h). The obtained vanadium dioxide film after annealing is gray.

In step (6), after the spraying is completed, the heating of the electric heating plate is stopped after spraying. The electric heating plate is allowed to cool naturally to room temperature to obtain a thermistor device. A resistance of the prepared thermistor device is about 5 Ω at room temperature.

In step (7), the thermistor device is connected in parallel with a semiconductor bridge. Under applying a fixed current for 5 min, it is observed that without the parallel vanadium dioxide thermistor, the temperature of the semiconductor bridge rapidly exceeds 200° C. under a 1.2 A current. With the parallel vanadium dioxide thermistor, the temperature of the semiconductor bridge is effectively reduced. Under a 1.5 A test condition, the equilibrium temperature remains below 200° C. The prepared thermistor thus provides effective current protection for the SCB.

### Comparative Embodiment 1

In step (1), under the room temperature, 2 g of vanadyl acetylacetonate is dissolved in 50 mL of anhydrous methanol to obtain a vanadyl acetylacetonate methanol solution.

In step (2), a ceramic tile coated with an interdigitated electrode is placed on an electric heating plate with a surface temperature of 350° C. to obtain a heated interdigitated electrode. The interdigitated electrode is fabricated on a 1 cm×1 cm aluminum oxide ceramic substrate. The interdigitated electrode has 15 pairs of interdigitated fingers with a line spacing of 50 μm, a line width of 100 μm, and a finger length of 7.7 mm.

In step (3), the vanadyl acetylacetonate methanol solution obtained in step (1) is sprayed onto a surface of the heated interdigitated electrode via an atomizing nozzle, and a distance between the atomizing nozzle and the surface of the electric heating plate is 5 cm.

In step (4), a spray flow rate is controlled at 50 mL/min, a spraying time is controlled at 20 min, and a vanadium dioxide film is prepared with a thickness of 1 μm.

In step (5), the prepared film is annealed at 400° C. and Ar₂ atmosphere for 3 h. The obtained vanadium dioxide film after annealing is gray.

In step (6), after the spraying is completed, the heating of the electric heating plate is stopped after spraying. The electric heating plate is allowed to cool naturally to room temperature to obtain a thermistor device. A resistance of the prepared thermistor device is about 9 Ω at room temperature.

In step (7), when the resistance in step (6) does not decrease below 5 Ω, the shunting effect is therefore unsatisfactory. Consequently, no SCB safety current experiment is conducted.

### Comparative Embodiment 2

A VO₂ serpentine thermistor is prepared by magnetron sputtering. The process includes the following steps (1)-(4).

In step (1), silicon is used as a substrate, and the substrate is cleaned and then dried with nitrogen gas for subsequent use.

In step (2), a mechanical pump is turned on to evacuate to 20 pascals (Pa). A molecular pump is then turned on. When the pressure reaches 5.0×10⁻⁴ Pa, a flow display meter is opened, and argon gas is introduced.

In step (3), a substrate temperature is set to 60° C. Pre-sputtering is performed on a surface of a vanadium target for 20 min to 30 min. Contaminants or other oxides are removed from the surface of the vanadium target. Oxygen gas is introduced, and a flow ratio between oxygen gas to argon gas is 0.01. The substrate temperature is set to 300° C. An alternating current target is used to sputter for 30 min.

In step (4), annealing is performed in a pure nitrogen atmosphere with a temperature of 400° C. Annealing is conducted for 1 h. The temperature is then lowered to room temperature. The sample is removed.

The prepared vanadium oxide thermistor device has a film thickness of 500 nanometers (nm), and a resistance after the phase transition of 15 Ω. The shunting effect is inferior to that of the 3 μm thick-film thermistor. The film thickness can be increased by extending the magnetron sputtering time. However, this method increases the cost, and also increases film stress, which may cause the film to peel off from the substrate surface. Therefore, the magnetron sputtering method is not suitable for producing very thick films. The performance of the vanadium dioxide thermistor prepared by this method is currently inferior to that of the method described in the disclosure.

The foregoing describes specific implementations of the disclosure. However, a protection scope of the disclosure is not limited thereto. Those skilled in the art can readily conceive of changes or substitutions within a technical scope disclosed herein. All such changes or substitutions shall fall within the protection scope of the disclosure.

What is claimed is:

1. A method for semiconductor bridge current protection based on a vanadium dioxide thick-film thermistor, comprising:
S1, dissolving vanadyl acetylacetonate in a methanol solution to obtain a vanadyl acetylacetonate methanol solution, wherein a molar concentration of the vanadyl acetylacetonate in the vanadyl acetylacetonate methanol solution is 0.151 moles per liter (M);
S2, obtaining an interdigitated electrode, and heating the interdigitated electrode to maintain a temperature of the interdigitated electrode at 300 Celsius degrees (° C.) to 400° C. to obtain a heated interdigitated electrode;
S3, spraying the vanadyl acetylacetonate methanol solution obtained in step S1 onto a surface of the heated interdigitated electrode obtained in step S2, wherein during the spraying, the temperature of the interdigitated electrode is maintained at 300° C. to 400 ° C., and an M-phase vanadium oxide film with a thickness of 2 microns (μm) to 5 μm is deposited on the surface of the heat interdigitated electrode via spraying;
S4, after the spraying is completed, annealing the interdigitated electrode and the M-phase vanadium oxide film, followed by naturally cooling to room temperature to obtain a thermistor device; wherein the thermistor device comprises the interdigitated electrode and the M-phase vanadium oxide film deposited thereon; and
S5, connecting the thermistor device in parallel with a semiconductor bridge to achieve thermistor-based semiconductor bridge current protection.

2. The method for semiconductor bridge current protection based on the vanadium dioxide thick-film thermistor as claimed in claim 1, wherein the step S2 specifically comprises: placing a substrate coated with the interdigitated electrode on an electric heating plate for heating, wherein a surface temperature of the electric heating plate is controlled at 300° C. to 400° C.

3. The method for semiconductor bridge current protection based on the vanadium dioxide thick-film thermistor as claimed in claim 2, wherein the substrate is any one of alumina ceramic and a silicon substrate with a surface-grown oxide layer.

4. The method for semiconductor bridge current protection based on the vanadium dioxide thick-film thermistor as claimed in claim 1, wherein the spraying in step S3 specifically comprises: spraying via an atomizing nozzle.

5. The method for semiconductor bridge current protection based on the vanadium dioxide thick-film thermistor as claimed in claim 4, wherein the spraying via an atomizing nozzle specifically comprises: controlling a distance between the atomizing nozzle and an upper surface of the interdigitated electrode to be 5 centimeters (cm) to 20 cm; and controlling a spray flow rate to be 20 milliliters per minute (mL/min) to 50 mL/min, and controlling a spraying time to be 30 minutes (min) to 40 min.

6. The method for semiconductor bridge current protection based on the vanadium dioxide thick-film thermistor as claimed in claim 1, wherein the interdigitated electrode is one selected from the group consisting of a copper interdigitated electrode, a nickel interdigitated electrode, and a gold interdigitated electrode.
